(19) United States
(12) Patent Application Publication
(10) Pub. No.: US 2009/0167380 A1
(43) Pub. Date: Jul. 2, 2009

(54) System and method for reducing EME emissions in digital desynchronized circuits

(76) Inventor: Christos P. Sotiriou, Heraklion (GR)

Correspondence Address: STEPTOE & JOHNSON LLP, 1330 CONNECTICUT AVENUE, N.W., WASHINGTON, DC, 20036, US

(21) Appl. No.: 12/003,468

(22) Filed: Dec. 26, 2007

(51) Int. Cl. H03L 7/00

(52) U.S. Cl. 327/153

(57) ABSTRACT

A system includes first and second synchronous circuits and an asynchronous circuit configured to receive input from the first synchronous circuit and to send output to the second synchronous circuit. First and second variable clock generators are configured to drive the first and second synchronous circuit. A delay circuit is configured in a pathway from the first variable clock generator to the second variable clock generator, the delay circuit being configured to add a delay to the pathway based upon a processing time or an expected processing time of the asynchronous circuit. The delay circuit is further configured to induce additional uneven delay into the pathway. The additional uneven delay disperses local current absorption, thereby decreasing overall electro magnetic emissions of the system.

### BACKGROUND OF THE INVENTION

1. Field of the Invention

The present invention relates to reducing Electro-Magnetic Emissions (EME) of integrated circuits. More specifically, the present invention relates to modifying the current absorption of circuits as dictated by the phase of the locally-generated desynchronization clock signals to reduce the overall EME of a desynchronized circuit.

2. Discussion of Background Information

Digital circuits (ASICs) may have high electro magnetic emissions (EME) due to the fact that either (i) all sequential elements (registers/latches) are simultaneously clocked by a single clock or (ii) a very large number of sequential elements (e.g. 500 K) or more are clocked by a single clock in a multiple clock design. In such synchronous environments, the circuit absorbs current for the switching of the sequential elements at the same time, resulting in a high overall EME. In certain application domains, such as mixed analog-digital circuits (e.g., pagers, cellphones, automotive applications), the high EME of digital parts have a significant effect on the noise absorbed by the analog parts.

Desynchronization is an approach whereby a synchronous circuit is transformed into desynchronized equivalent by altering the clocking approach of the original circuit. Instead of a single or multiple global clock signals, the original circuit is divided into a number of so-called desynchronization regions. Each of these regions typically includes a combinational logic cloud, and a set of relevant registers connected at the input and output of that cloud, a single clock generating element, a so-called desynchronization controller, and a delay-element, which is used to delay the local clock signal appropriately from cycle to cycle based on the time delay of the corresponding combinational logic cloud. FIG. 1(a) and FIG. 1(b) show an example of a synchronous circuit and its equivalent desynchronized one. FIGS. 2 and 3 show examples of a translation of a more complicated synchronous circuit to a desynchronized circuit.

Such desynchronized circuits may have high electro magnetic emissions (EME), although usually not at the same levels as their equivalent synchronized circuits due to the different local clock speeds for the desynchronized regions. The reason is that the circuit is no longer operating according to a global clock, but rather to multiple desynchronized clocks which “spread” the current absorption characteristics of the circuit over the frequency domain.

Specifically, when a desynchronized circuit operates after its reset signal is released the local clocks will firstly enter a temporary, transient state. Their edges will for a short number of cycles tend to remain non-periodic and out of lockstep, i.e. unrelated between them, even though the underlying data-flow will be correct. This transient behavior stems from the relationship between the desynchronization regions, which allows momentarily data to flow and clocks to operate unimpeded. Eventually synchronization points between desynchronization regions (e.g., data path forks and joins) push the circuit out of the transient behavior for the local clock edges and all the clocks to settle into a periodic, repetitive behavior. The local desynchronized clock signals will move into cycle to cycle lockstep, for a given reference clock edge.

A desynchronized circuit typically has two clock signals per clock generator pair and desynchronization region. This is because desynchronization, in order to tolerate timing skew between any local clocks, transforms the original synchronous circuit's registers, i.e. the synchronous design's Flip-Flops, into a pair of Master-Slave operated, level-sensitive latches, which are driven by the desynchronization clock generators. Typically, one clock generator controls the Master Latches and one the Slave Latches for a given region.

After the desynchronized circuit's clocking has settled into a repetitive, periodic behavior, all clock signals will assume a given and identical operating period. This period is a function of the manufacturing process, P, and should only be affected by changes in the temperature, T or operating Voltage, Vdd. Thus, for a given (P, V, T) point, all the clocks will, in their settled state, assume the same period. However, not all clocks will assume the same phase with the others, which stems from the fact that each local clock is generated by causal logic, i.e. a clock edge is a consequence of one or previous clock edges. In addition, each delay element can shift its local clock's phase in time, by an amount proportional to its timing delay. Thus, once a desynchronized circuit has settled for a given (P, V, T) point, into a periodic, repetitive clocking pattern, it is possible to measure: (i) its operating period (the timing delay between two edges of the same type (rising or falling) of a local clock signal), and (ii) the phase differences between the different desynchronized clock signals (the delay of an edge of one clock to the first edge of another clock of the same type).

For a desynchronized circuit in which the clocks have reached their equilibrium, periodic and lockstep operation, the relative phases between one arbitrary reference desynchronization clock and all the others can be measured. These original phases of the desynchronized circuit are a function of: (i) the connectivity of the desynchronized system, specifically fork and join points between desynchronization regions, where synchronization occurs (thus certain clocks are strictly synchronized with others, whereas others are unrelated) and (ii) the length and corresponding delay of the delay element of each desynchronization region, in which the original desynchronization idea will be a function of the delay of the combinational logic cloud of the desynchronization region plus a given degree of safety timing margin to account for (P, V, T) mismatches between the delay element and the actual logic itself.

The graph in FIG. 4 illustrates these principles as applied to differences between synchronous and desynchronized circuits. Presume that an original synchronous circuit with a synchronized clock is translated into a desynchronized circuit with two (2) clocks. The peaks 410 represent the current surge which occurs when the clock in the original synchronous circuit switches the sequential elements of a circuit, whereas peaks 420 and 430 represent the current surge which occurs when the two clocks in the equivalent desynchronized circuits switch the sequential elements of a circuit. Due to the translation, what was once a peak of the original synchronous circuit is spread into two separate peaks for the corresponding equivalent desynchronized circuit. The first peak 420 occurs again at frequency f0, which is the inverse of the identical periods of peak 420 and 430. The second peak 430 occurs at the higher frequency, fhi, which preferably is the inverse of the phase or timing delay between peaks 420 and 430. Less elements switch at any given time in the desynchronized circuit, thus spreading the peaks in the frequency domain with a corresponding reduction in EME. However, these peaks remain significant in the desynchronized circuit (albeit less than the synchronous counterparts) and can have undesirable effects on the entire device of which the circuit is a part.

### SUMMARY OF THE INVENTION

This invention relates to reducing the EME of desynchronized circuits by various non-limiting methodologies. One embodiment modifies locally the phases of the desynchronized clock signals as they are produced out of the desynchronized clock controllers by appropriately tuning the delays of the relevant delay elements. Thus the circuits local timing delay is not selected to necessarily match the delay of its related combinational logic cloud, but rather is increased to appropriately position the local phase of the clock for globally best EME. Another embodiment introduces a varying jitter through a delay element to a local clock, i.e. an artificially injected uncertainty that spreads out current and lowers EME. Such phase spreading can be applied to some or all desynchronization clock signals. These approaches may potentially increase the period of the desynchronized circuit if they are applied at the region of longer local delay, which ultimately will determine the desynchronized circuit's cycle time.

According to an embodiment of the invention, a system is provided. The system includes first and second synchronous circuits and an asynchronous circuit configured to receive input from the first synchronous circuit and to send output to the second synchronous circuit. First and second variable clock generators are configured to drive the first and second synchronous circuit. A delay circuit is configured in a pathway from the first variable clock generator to the second variable clock generator, the delay circuit being configured to add a delay to the pathway based upon a processing time or an expected processing time of the asynchronous circuit. The delay circuit is further configured to induce additional uneven delay into the pathway. The additional uneven delay disperses local current absorption, thereby decreasing overall electro magnetic emissions of the system.

The above embodiment may have various optional features. The delay circuit can be configured to introduce different delay times to the pathway to induce unevenness. The different delay times may be preset, based on prime numbers, and/or randomly selected. At least one of the different delay times may include a delay time of zero. The delay circuit may include a multiplexer configured to receive and select amongst a plurality of different delay times. The delay circuit may be configured to receive a signal on the pathway, add a plurality of different delay times to the signal, to thereby create a plurality of different signals, select from amongst the plurality of different signals, and output the selected one of the different signals to the pathway.

According to another embodiment of the invention, a system is provided including a plurality of logic circuits and a plurality of delay circuits corresponding to respective ones of the plurality of logic circuits. Each of the plurality of delay circuits has a minimum delay which is equal to or exceeds a maximum running time of its correspond logic circuit. A plurality of variable clock generators are each driven based on at least the plurality of delay circuits, respectively. At least some of the delay circuits are configured to induce unevenness in delays between specific variable clock generators. The unevenness disperses current absorption of the system, thereby decreasing overall electro magnetic emissions.

The above embodiment may have various optional features. The plurality of delay circuits may be configured to select amongst a plurality of delay times greater than a minimum delay time. The variable delay circuit may be configured to select between a minimum delay time and at least one other delay time greater than the minimum delay time. The plurality of delay times may be selected based upon at least one of random, semi-random, or round robin methodologies. The variable delay circuit may include a multiplexer that receives the minimum delay time and at least one other delay time greater than the minimum delay. The multiplexer may be controlled based upon at least one of random, semi-random, or round robin methodologies.

According to yet another embodiment of the invention, a system is provided including first and second desynchronized regions of logic circuits configured to exchange control signals. The second region includes at least first and second independent desynchronized sub-regions each having independent local clocks and independent delay circuitry. An interface is configured to receive control signals intended for the first desynchronized region from the first and second independent desynchronized sub-regions, pass the control signals intended for the first desynchronized region when in agreement, and block the control signal intended for the first desynchronized region when not in agreement.

The above embodiment may have various optional features. The delay circuitry of the first and second independent desynchronized sub-regions may be different from each other. The delay circuitry of the first and second independent desynchronized sub-regions may have different physical structures. The delay circuitry of the first and second independent desynchronized sub-regions may have different controlling algorithms.

### BRIEF DESCRIPTION OF THE DRAWINGS

The present invention is further described in the detailed description which follows, in reference to the noted plurality of drawings by way of non-limiting examples of certain embodiments of the present invention, in which like numerals represent like elements throughout the several views of the drawings, and wherein:

FIGS. 1(a)-(b) illustrates a translation of a prior art linear synchronous pipeline into its equivalent desynchronized circuit.

FIG. 2 illustrates another prior art linear synchronous pipeline into its equivalent desynchronized circuit.

FIG. 3 illustrates a translation of the circuit in FIG. 2 into its equivalent desynchronized circuit.

FIG. 4 illustrates an example of spreading current absorption for a synchronous circuit compared with an equivalent desynchronized circuit.

FIG. 5 illustrates an example of spreading current absorption for a synchronous circuit compared with an equivalent desynchronized circuit having calibrated phases.

FIGS. 6(a) and 6(b) illustrate another equivalent desynchronized circuit compared with an equivalent desynchronized circuit having calibrated phases.

FIG. 7 illustrates a time diagram of the circuit in FIG. 6(a).

FIG. 8 illustrates a phase diagram of the time diagram in FIG. 7.

FIG. 9 illustrates a time diagram of the circuit in FIG. 6(b).

FIG. 10 illustrates a phase diagram of the time diagram in FIG. 9.

FIG. 11 illustrates graphs of the EME output of the circuits in FIGS. 6(a) and 6(b).

FIG. 12 illustrates graphs of the Power output of the circuits in FIGS. 6(a) and 6(b).

FIGS. 13(a) and (b) illustrate an embodiment of the invention for inducing jitter.

FIG. 14 illustrate another embodiment of the invention for inducing jitter.

FIG. 15 illustrates an embodiment of the invention utilizing additional desynchronized clocks.

FIG. 16 is a flowchart of an algorithm for optimizing the reduction of EME in the circuit of FIG. 18.

FIG. 17 is a graph of EME measurements of fabricated integrated circuit design of a synchronous circuit.

FIG. 18 is a graph of EME measurements of fabricated integrated circuit design of an equivalent desynchronized circuit for the circuit of FIG. 19.

FIG. 19 is a circuit of an embodiment of the invention.

### DETAILED DESCRIPTION OF THE EXEMPLARY EMBODIMENT

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the several forms of the present invention may be embodied in practice.

At a conceptual level, embodiments of the invention alter the original, equilibrium state phases of the desynchronized local clocks. Specifically, the more that current absorption spreads within the clock period in non-multiples of a given frequency, the lesser the EME emissions at the frequencies implied by the phases of the desynchronized clocks. This effect results from the spreading of EME to different frequencies, as opposed to accumulating at a specific frequency.

Even phase spreading of desynchronized clocks, while within the scope of the invention, is not preferable for minimizing as it merely represents a time shift with the same frequency of operation that does not significantly impact EME emissions. However, if the phases between desynchronized clocks are made intentionally uneven an EME improvement will be observed, as only a part of the clock edges will accumulate onto the same frequency harmonics in the frequency domain. In this context, unevenness is the intentional shifting of clock signals (which may be uneven themselves) from their normal operating state.

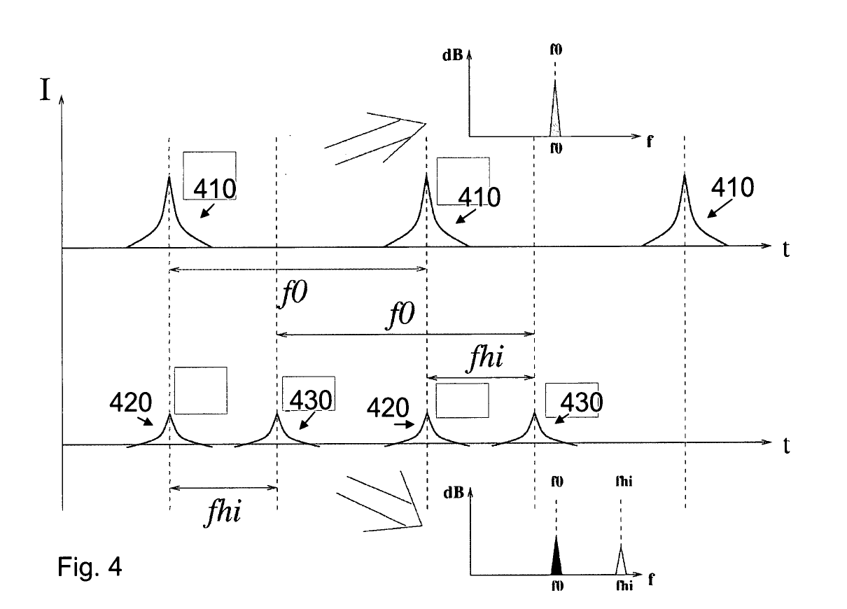

This EME distribution methodology also leverages the inherent capacitances in most circuits that exist from the power supply to the ground node. Such capacitances will have little effect on a single high EME pulse or even a limited number of smaller peaks such as shown in FIG. 4 because of the high energy content in the higher peaks. In contrast, the spreading methodologies herein spread the EME into a number of individual smaller peaks on which the capacitances can have significant impact on (if not completely neutralize) each individual peak, and thus the global EME of the circuit.

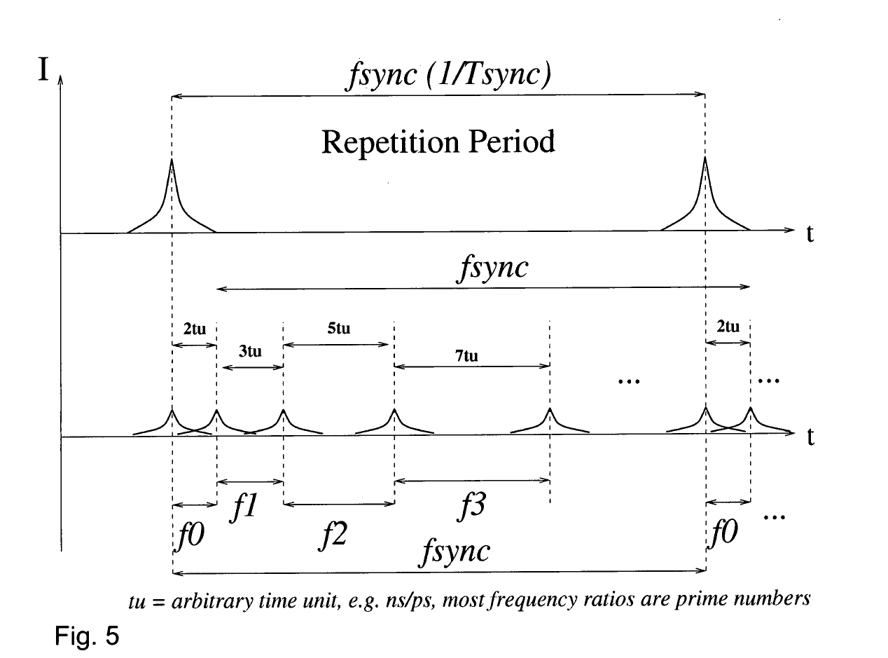

The graphs of FIG. 5 illustrate this principle as applied to differences between a synchronous circuit and an equivalent desynchronized circuit that intentionally induces unevenness into the clock phases. In the lower graph, the individual clock phases are calibrated based on prime numbers, such that the local desynchronized clock phases are not multiples of each other and do not accumulate on the same frequency harmonics. The natural parasitic capacitances of the underlying circuit will more effectively filter out these smaller peaks.

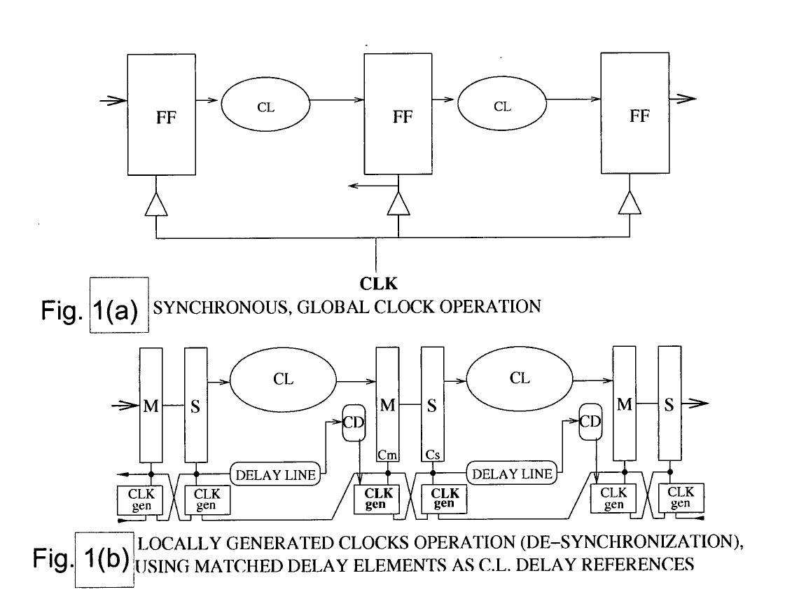

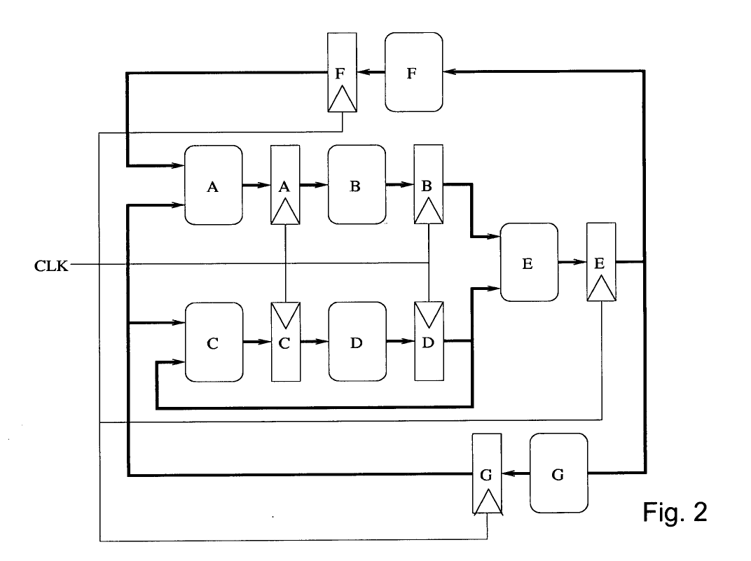

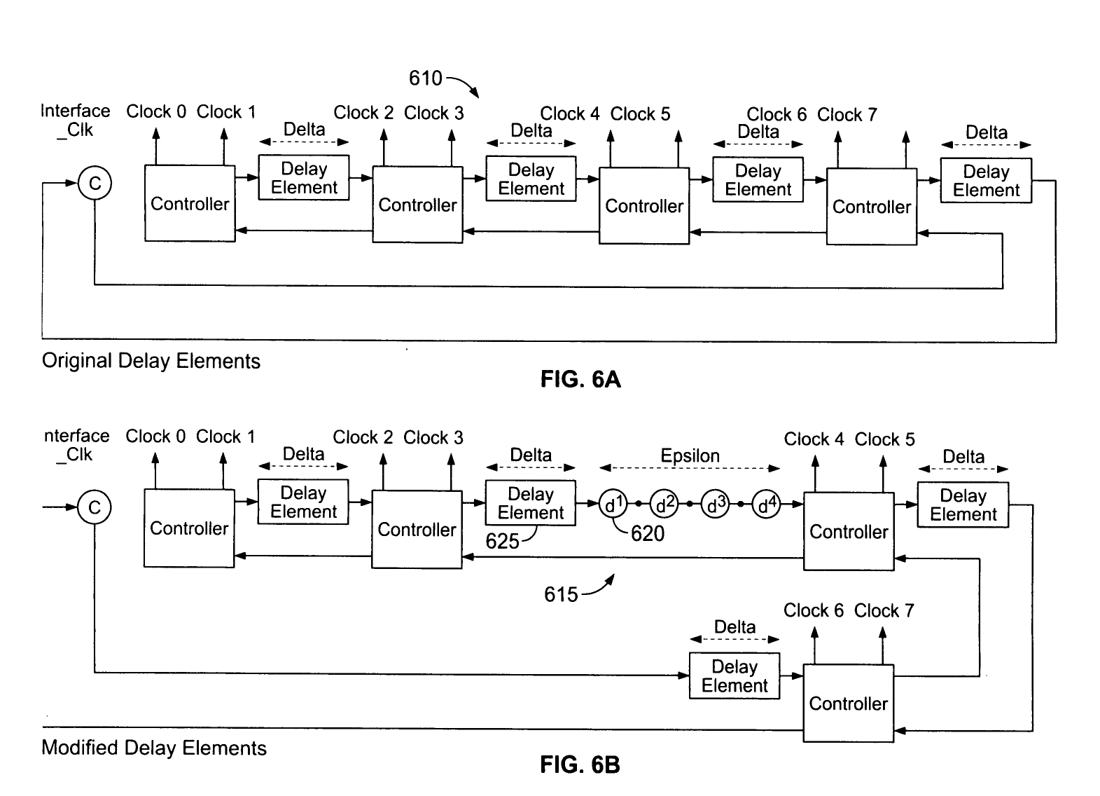

The required calibration can be implemented through appropriate circuit implementation of the length of delay elements, or by a combination of appropriate circuit implementation and post-manufacturing delay tuning of the delay elements. FIGS. 6(a) and 6(b) are non-limiting examples of such a circuit implementation. FIG. 6(a) illustrates a basic desynchronized control and clock circuit 610 similar to that shown in FIG. 1(a). FIG. 6(b) shows a circuit 615, which corresponds to circuit 610 with the addition of various epsilon delay elements 620 introduced downstream of a delay element 625. Delay element 625 preferably has a delay that mimics that of the asynchronous circuit to which it is associated, e.g., delay element 625 can be a completion detection circuit of the associated asynchronous circuit, or has a pre-set delay based on what the delay is expected to be under worst case processing time of the associated asynchronous circuit.

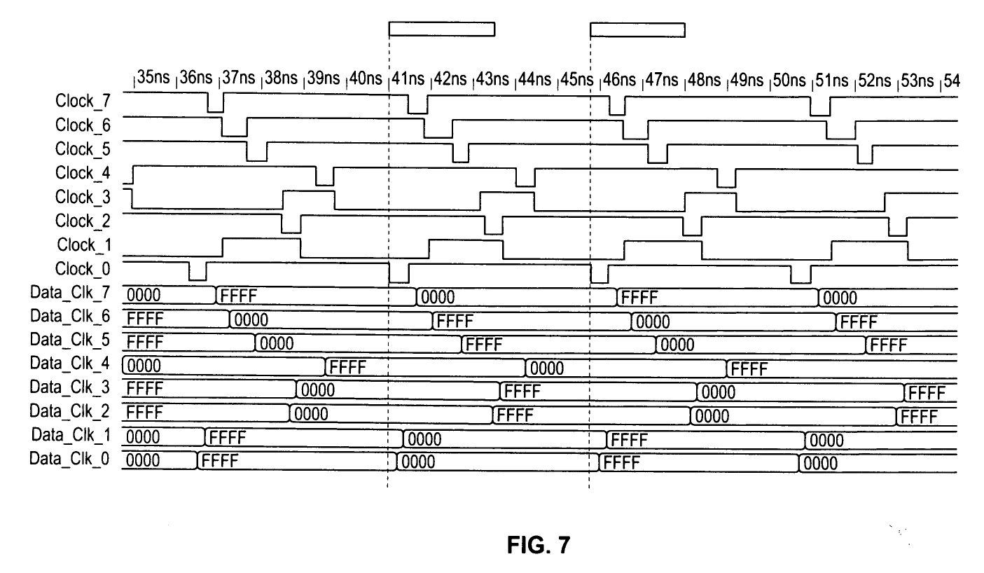

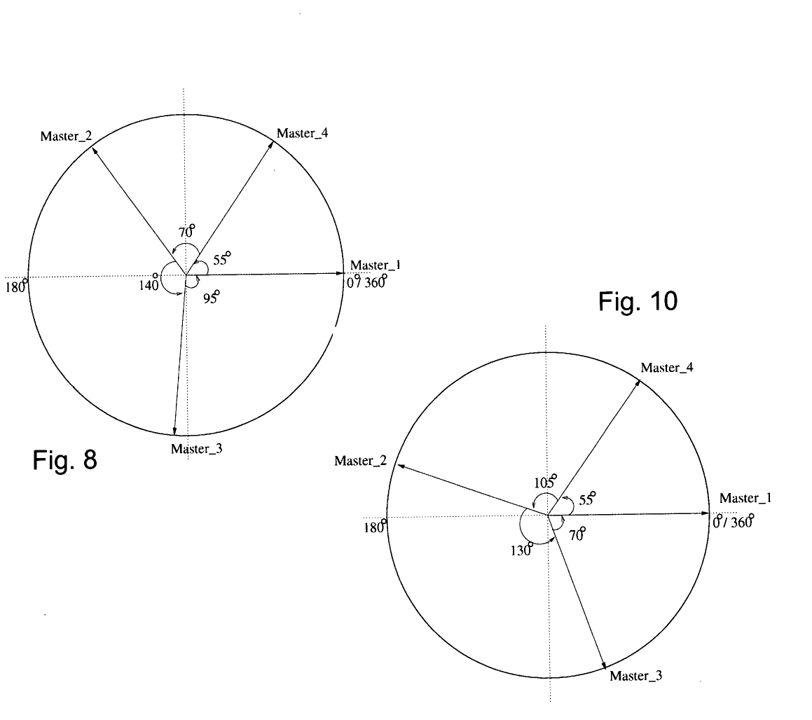

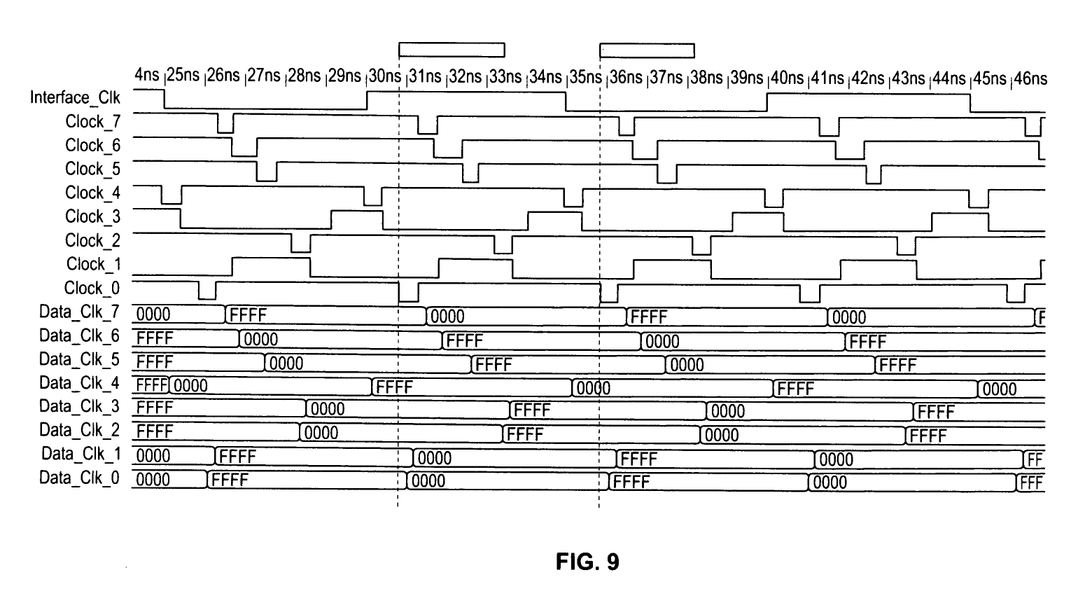

Operative differences between the circuits shown in FIGS. 6(a) and 6(b) are shown with reference to FIGS. 7-10. FIG. 7 illustrates an example of the timing diagram of the circuit in FIG. 6(a), and FIG. 8 is a phase diagram of the timing diagram shown in FIG. 7. The timing diagram demonstrates the possible shapes in the time domain of the desynchronized clock signal waveforms with non-limiting examples of data aligned to these clocks. In FIG. 7, the period of operation is 5 ns and the clock signals at the top correspond to Master and Slave desynchronization clock pairs, where the top one is the Slave of a desynchronization controller, the second from the top is a Master, etc. FIG. 8 shows the resulting phase alignments when the circuit has entered its equilibrium, periodic state. By way of comparison under identical conditions, FIG. 9 illustrates an example of the timing diagram of the circuit in FIG. 6(b), and FIG. 10 is the corresponding phase diagram.

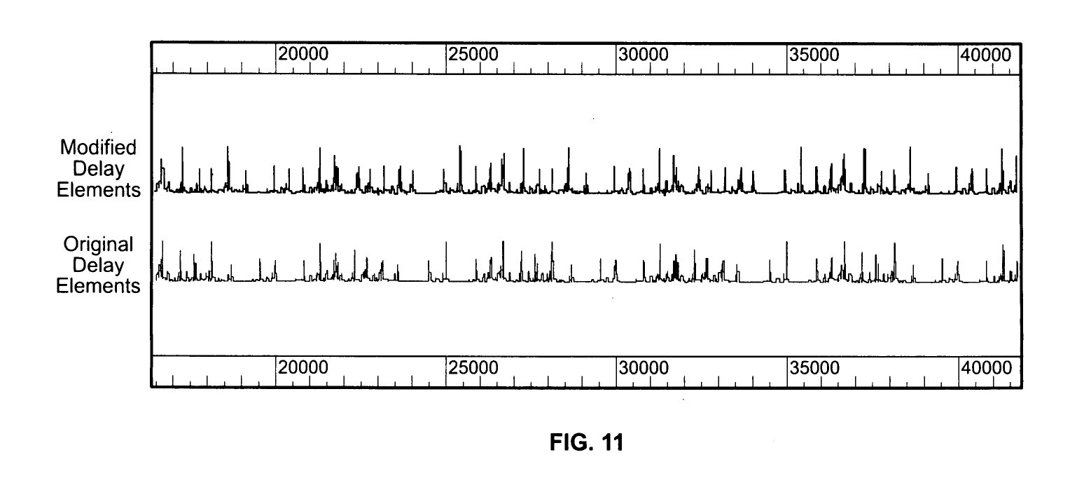

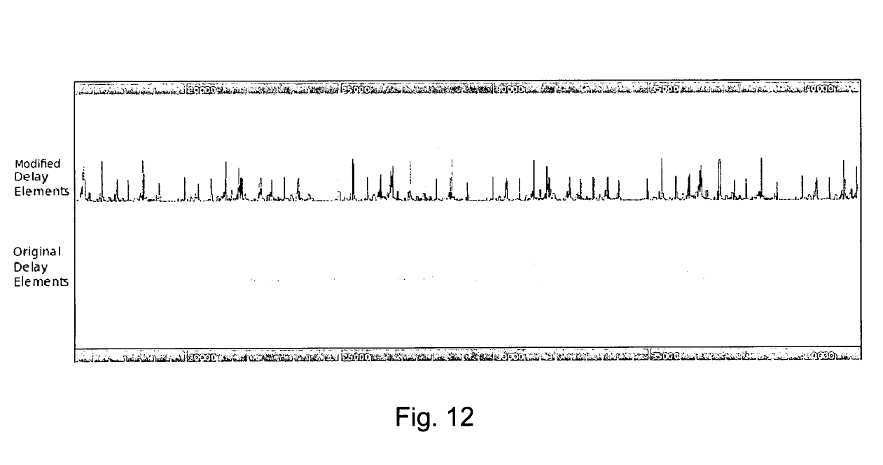

The resulting EME emissions based on the above is shown in FIG. 11, in which the top graph is the EME emissions of the circuit in FIG. 6(a) and the bottom graph is the EME emission of the circuit in FIG. 6(b). The EME of the original synchronous circuit is significantly higher than the desynchronized circuit incorporating an embodiment of the invention, particularly at frequencies at which for the original synchronous circuit had larger EME spikes. FIG. 12 shows the corresponding power analysis, in which the bottom graph represents the circuit of FIG. 6(a) and the top graph represents the circuit of FIG. 6(b). These graphs illustrate the nature of the EME gains as a result of the current spreading effect.

Another embodiment of inducing unevenness is by incorporating an artificial jitter or dynamic skew of arbitrary magnitude to one or several clocks. Such an embodiment dynamically alters delay element length and delay during the circuit's operation and shifts constantly (at a given rate) the current absorption dictated by the clocks to which the dynamic jitter is applied. The constant shifting reduces the accumulation of power at certain frequencies and spreads the EME power over a given band of frequencies, thus making it less significant and more susceptible to removal through the natural parasitic capacitances of the circuit.

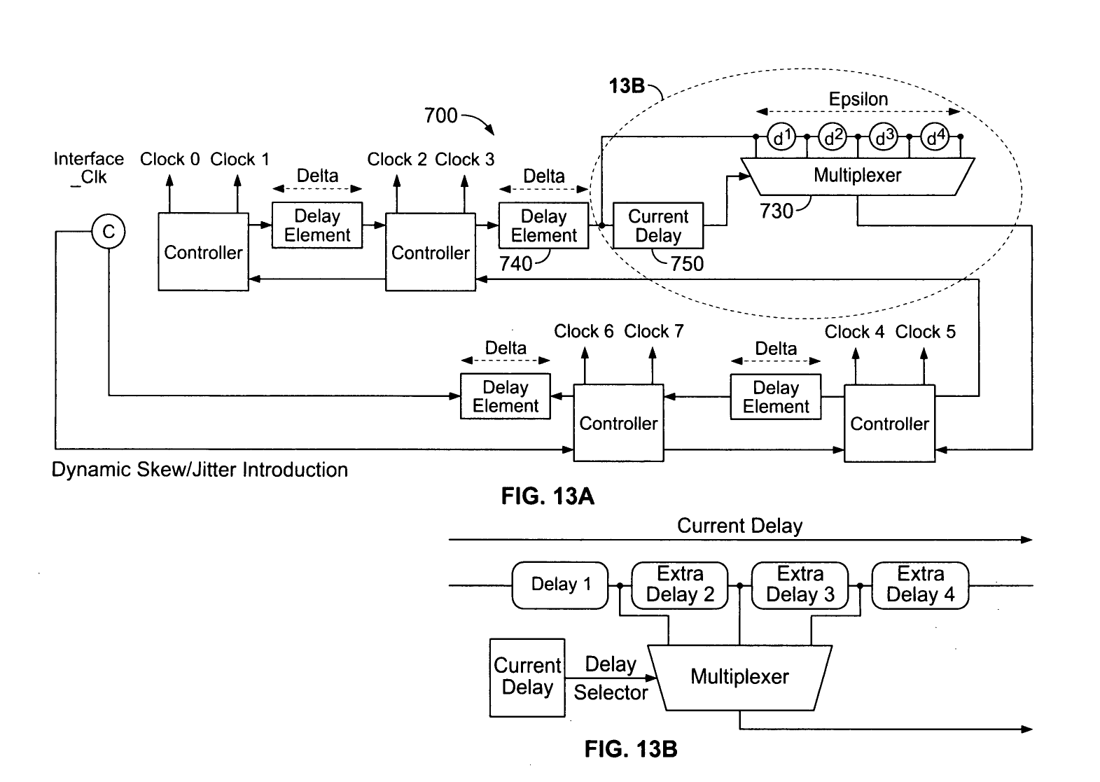

FIGS. 13(a) and (b) illustrates a circuit 700 configured to induce such an artificial jitter. A variable delay element is essentially a multiplexer 730 that uses multiple taps in which the individual delay elements g1-g4 are sequentially added in series to the incoming delay as set by delay element 740. Multiplexer 730 inputs are taken between the individual delay elements. The various available delay times g1-g4 are preferably different from each other and may be in increasing order (e.g., g1=1 ns, g2=1.1 ns, g3=1.2 ns, etc.), but neither is required. Multiplexer 730 selects one of delay times under control of a delay selector 750 using any desired methodology. Non-limiting examples include round robin, random, semi-random (e.g., using a Linear Feedback Shift Register) etc. Selections can be weighted, so that one or more delay times are selected more often than other delay times.

In order to select correctly the desired delay, the control signal from delay selector 750 preferably stabilizes before variable delay element 740 is used. Delay selector 750 can change state while delay element 740 is inactive and waiting for another input. The delay element 740 is preferably not in use while delay selector 750 is changing state.

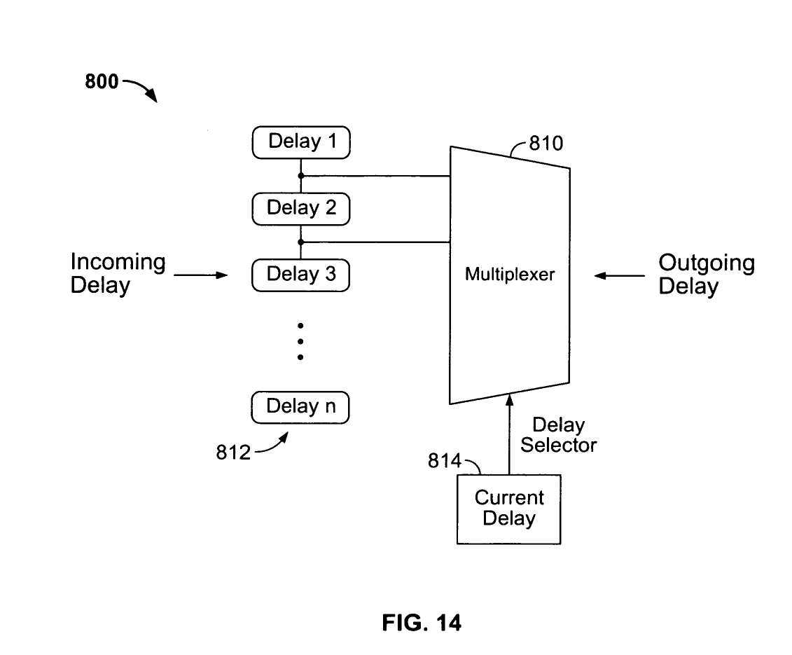

FIG. 14 shows an alternative design of using a multiplexer to introduce artificial jitter. Rather than driving each of the inputs of the multiplexer with sequentially added delays in series, the configuration of FIG. 13 uses multiple taps to directly present the individual delays.

Skew can also be injected into the circuit of FIG. 1(b) by adding delay to the outgoing completion detection signal from completion detection circuit before it arrives at a clock generator. A non-limiting example would be to insert the delay circuit of FIG. 13 or 14 between the completion detection circuit and the clock generator. In this implementation, the additional delay times would add to the completion detection signal. A delay time could be zero (e.g., just a wire connecting the completion detection signal directly into an input of the multiplexer) to allow for the originating completion signal to drive the clocks.

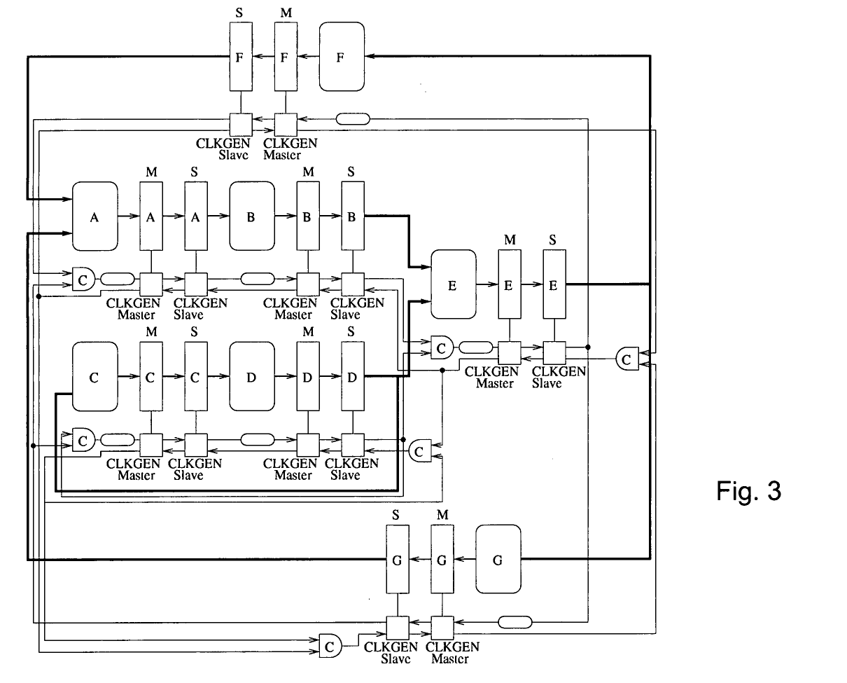

Another embodiment of inducing unevenness introduces more desynchronized clocks. This involves adding more desynchronization regions while obeying and preserving the desynchronized circuit structure, and making the timing of the desynchronized circuit more fine-grained, i.e. splitting the current peak of a single region to two or more regions. By introducing additional clocks, current peaks are split into more peaks and more freedom for adjusting the current absorption through further phase manipulation (e.g., but modifying the individual delay pathways in manners as discussed above). For example, one methodology is to redesign the entire circuit to distribute the asynchronous circuitry into a larger number of regions. For example, FIG. 3 shows seven (7) regions A-G with seven (7) corresponding control sets. The circuit could be redesigned to instead have eight (8) or more regions.

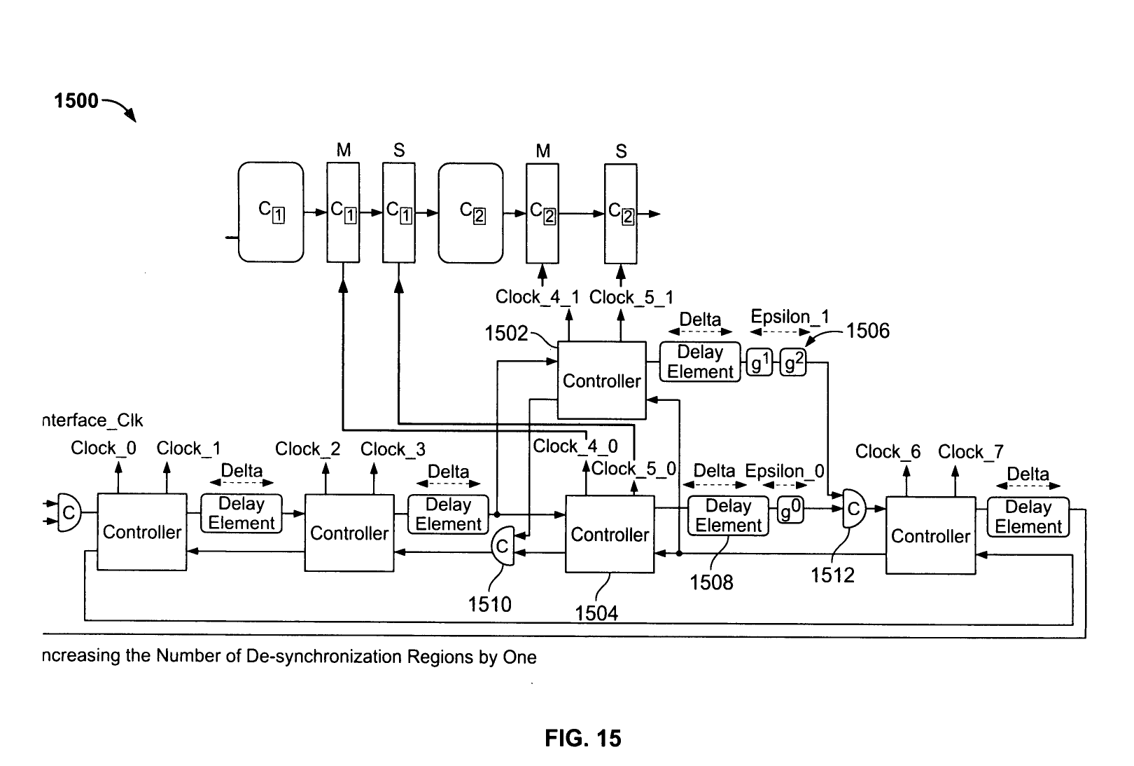

Another methodology is to take an individual asynchronous region (e.g., “C” in FIG. 3) and to break it up into individual sub-regions (C1, C2, etc.) under independent control circuitry. FIG. 15 shows a non-limiting example of the separating the control circuitry for a desynchronized region C into two sub-regions C1 and C2 1500. Each sub region has its own control circuitry 1502 and 1504 and independent delay circuitry. The delay circuitry structure 1506 and 1508 of the two sub-regions is preferably different so that the delays of the sub-regions will typically be different from each other to spread the current absorption.

The desynchronized regions maintain a data dependency, in that each region waits for (1) all its inputs from its predecessor upstream regions to arrive in order to produce outputs, and (2) of its successor regions to consume output data by reading acknowledge before accepting new inputs. The various control circuits therefore exchange control signals (sometimes referred to as acknowledge and request signals) to indicate an appropriate state of readiness. When a particular region is separated into sub-regions, the sub-regions collectively maintain that data dependency with respect to other desynchronized regions. By way of non-limiting example, the circuit of FIG. 15 has the upstream control signals from controllers 1502 and 1504 passing through a C gate 1510, and the downstream control signals as delayed passing through a C gate 1512. The C gates will not pass the control signals until both controllers agree as to their state. For example, if C1 is ready to receive input but C2, the C gate 1510 will not allow the controls signal from C1 to pass upstream because its controls signal is different from C2; when C2 is later ready to receive input, C1 and C2 will output a common control signal which the C gate will pass. By maintaining this data dependency, the individual sub-regions collectively appear and act as a single region.

All three of the above-modifications tend to incur a circuit area penalty. The area penalty of the methodology discussed with respect to FIG. 6(b) is proportional to the phase shifts that are required. The area penalty of the methodology of FIGS. 13(b) and 14 is proportional to the numbers of delay elements that have to be modified to introduce dynamic jitter and to the amount of dynamic jitter required. The area penalty of the methodology of FIG. 14 is proportional to the new number of desynchronization regions that are introduced.

The above embodiments are not mutually exclusive. Any combination of the three, either individually or repeatedly throughout the circuit, could be used. Preferably an appropriate computer algorithm can analyze a synchronous and/or desynchronized circuit and identify circuit modifications that can improve, and potentially optimize, EME reductions using the methodologies discussed herein. An algorithm for optimizing the EME, by using one or more of the embodiments herein is preferably based on automated trial and error nature to explore an optimized space along with a global minimum and avoidance of local minima.

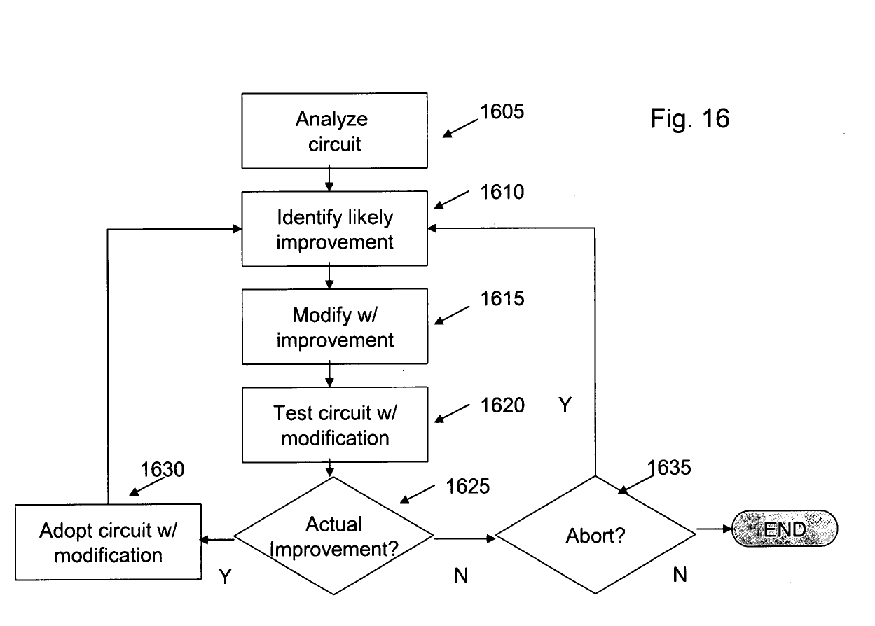

One methodology, preferably implemented by computer algorithm, is shown at FIG. 16. A specific circuit is analyzed at step 1605 to determine its base-line EME. At step 1610, a particular modification is identified as something which is likely to lead to an improvement in EME. The modification is made at step 1615 and the modified circuit is tested at step 1620 via simulation (discussed below) to determine whether the modification does in fact result in an EME improvement. The improvement analysis need not be limited to just improvements in EME, as it possible that a modification may improve EME to the detriment of other pre-defined circuit characteristics (e.g., circuit area).

If the modification results in the desired improvement, then at step 1625 the modification is applied at step 1630 and control returns to step 1610 for potential additional improvements. If the modification does not provide the desired improvement, then the modification is rejected and control passes to step 1635 to determine whether to abort the process. If the process is to be aborted, (typically after an elapsed period of time or when all potential modifications have been explored), then the program ends. If not, control returns to step 1610 to attempt to locate further improvements. In the alternative, the algorithm could explore groups/collections of various modifications rather than modifications on an individual basis.

The above algorithm preferably runs recursively, in that it will continue to explore alternatives at other modifications branch points. For example, even though the algorithm may identify several modifications which improve the circuit, there may be other combinations of modifications that provide superior results. Thus, the algorithm preferably explores all possible combinations. In addition and/or the alternative, the algorithm could “roll back” an improvement in the circuit in an attempt to locate another modification (or sequence of modifications) that yields superior results.

Another embodiment of the algorithm would allow the program at step 1620 to pursue, at least for a set time and/or number of tries) modifications that either do not improve or actually worsen EME. This may yield circuit modifications that would escape local EME minima yet collectively move toward a global EME minimum.

The testing at step S1620 above may either be direct simulation of the EME characteristics of the circuit, or an indirect test based on internal properties of the circuit and a local cost analysis. (The latter may be preferable under certain conditions, as EME measurement for every attempted modification may be impractical using current computer technology). Such an indirect analysis preferably is a function which assesses through a cost variable, whether the desynchronized clock phases are constant factors of each other, (amount of current spreading) and is inversely proportional to the number of desynchronized clocks (degree of current spreading). However, the invention is not so limited, and other methods may be used.

Applying the methodologies discussed herein can provide various advantages for the circuits. It can reduce the EME of a desynchronized integrated circuit design by: (i) modifying the desynchronized circuit's netlist either pre-layout, adding desynchronization regions and modifying the delay elements to be dynamic or calibrating their phases, and/or (ii) modifying the desynchronized circuit post-layout by modifying the delay-element cells using a limited cell change operation within the layout area (commonly referred to by Placement and Routing EDA tools as Engineering Change Order—ECO operation). A synchronous circuit can similarly receive the benefits of EME reduction by conversion to a desynchronized equivalent and application of the methodology as discussed herein.

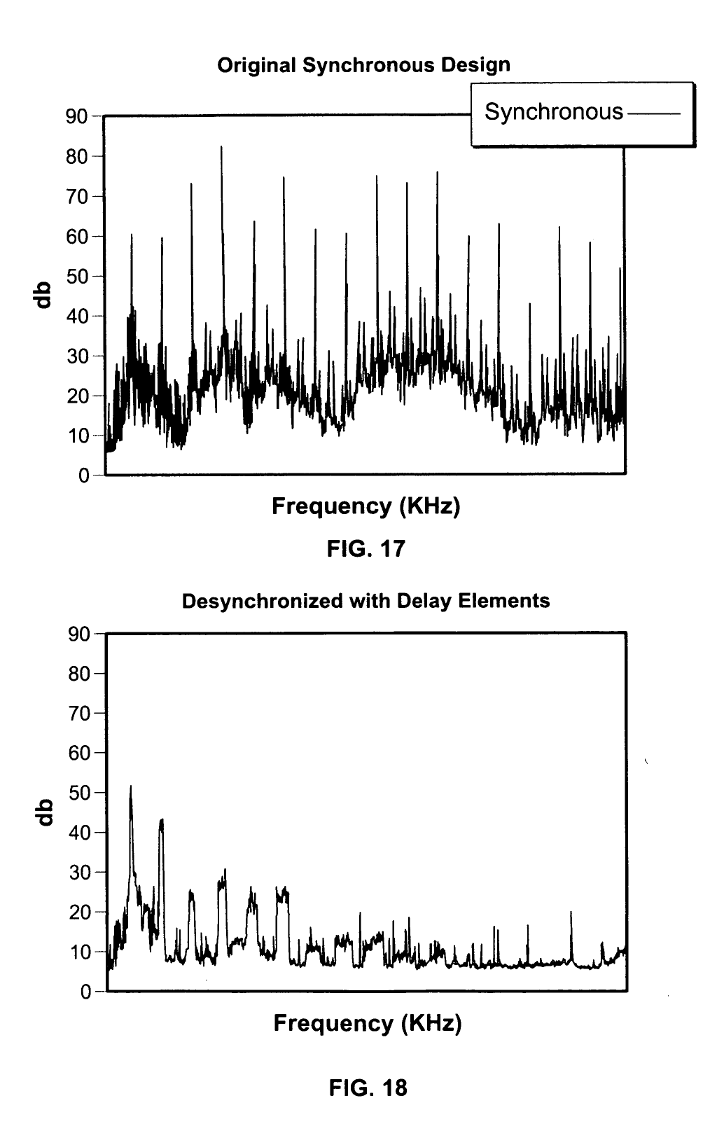

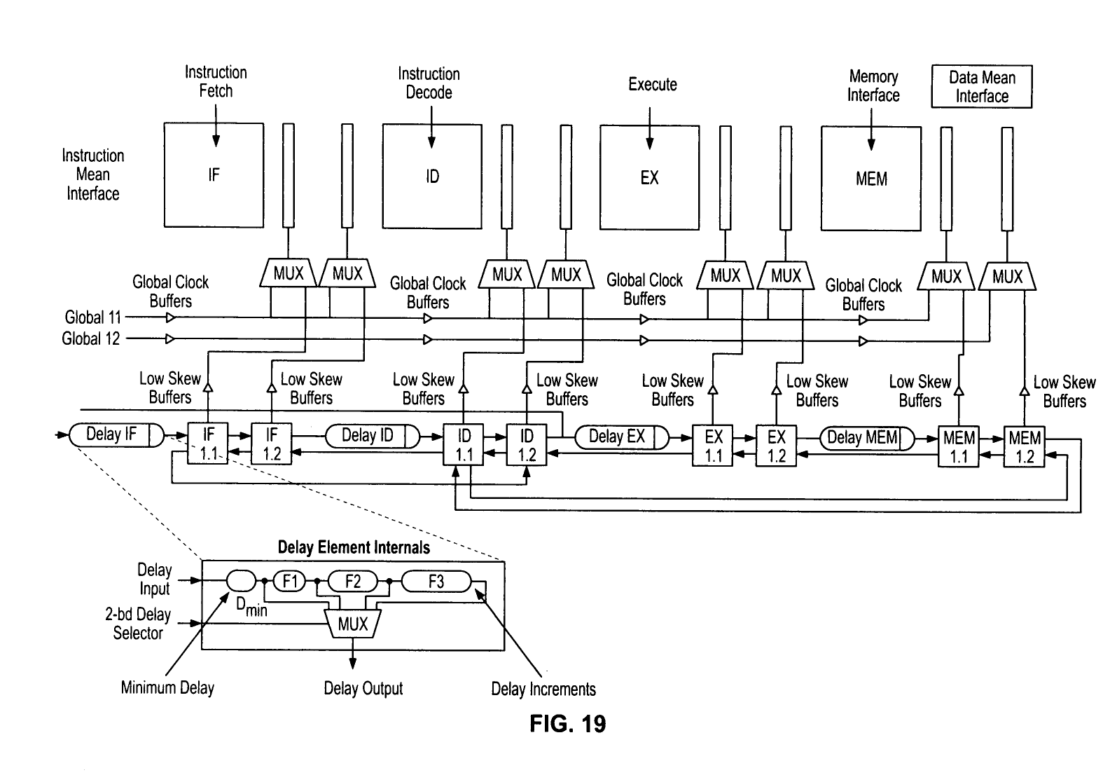

FIGS. 17 and 18 compare EME measurements as performed on a fabricated integrated circuit design shown in FIG. 19 for a synchronous circuit and its corresponding desynchronized circuit using the EME suppression techniques discussed herein. Once again, the comparison shows considerable reduction in the collective EME, particularly at peaks.

While the above discussion is directed to three preferred embodiments for dynamically or statically inducing variations in the EME peaks of circuits, the invention is not so limited. Any circuitry that induces changes in the EME characteristics of the circuit, either individually and/or in combination with embodiments as disclosed herein fall within the scope and spirit of the invention.

What is claimed is:

1. A system, comprising:
first and second synchronous circuits;
an asynchronous circuit configured to receive input from the first synchronous circuit and to send output to the second synchronous circuit;
first and second variable clock generators configured to drive said first and second synchronous circuit;
a delay circuit configured in a pathway from said first variable clock generator to said second variable clock generator, the delay circuit being configured to add a delay to said pathway based upon a processing time or an expected processing time of the asynchronous circuit;
said delay circuit being further configured to induce additional uneven delay into said pathway;
wherein said additional uneven delay disperses local current absorption, thereby decreasing overall electro magnetic emissions of the system.

2. The system of claim 1, wherein said a delay circuit is configured to introduce different delay times to said pathway to induce unevenness.

3. The system of claim 2, wherein different delay times are preset.

4. The system of claim 3, wherein said different delay times are based on prime numbers.

5. The system of claim 2, wherein said different delay times comprise an initial delay with sequentially added additional delays, and the delay circuit can select from the amongst the different delay times.

6. The system of claim 2, wherein the different delay times are randomly selected.

7. The system of claim 2, wherein at least one of the different delay times includes a delay time of zero.

8. The system of claim 1, wherein said delay circuit includes a multiplexer configured to receive and select amongst a plurality of different delay times.

9. The system of claim 1, wherein said delay circuit is configured to:
receive a signal on said pathway;
add a plurality of different delay times to said signal, to thereby create a plurality of different signals;
select from amongst the plurality of different signals; and
output the selected one of the different signals to the pathway.

10. A system, comprising:
a plurality of logic circuits;
a plurality of delay circuits corresponding to respective ones of said plurality of logic circuits, each of the plurality of delay circuits having a minimum delay which is equal to or exceeds a maximum running time of its correspond logic circuit; and
a plurality of variable clock generators, each being driven based on at least said plurality of delay circuits, respectively;
wherein at least some of the delay circuits are configured to induce unevenness in delays between specific variable clock generators.
wherein said unevenness disperses current absorption of the system, thereby decreasing overall electromagnetic emissions.

11. The system of claim 10, wherein said plurality of delay circuits are configured to select amongst a plurality of delay times greater than a minimum delay time.

12. The system of claim 11, wherein said variable delay circuit is configured to select between a minimum delay time and at least one other delay time greater than said minimum delay time.

13. The system of claim 11, wherein said plurality of delay times is selected based upon at least one of random, semi-random, or round robin methodologies.

14. The system of claim 10, wherein said variable delay circuit includes a multiplexer that receives said minimum delay time and at least one other delay time greater than said minimum delay.

15. The system of claim 15, wherein said multiplexer is controlled based upon at least one of random, semi-random, or round robin methodologies.

16. A system, comprising:
first and second desynchronized regions of logic circuits configured to exchange control signals;
said second region comprising at least first and second independent desynchronized sub-regions each having independent local clocks and independent delay circuitry;
an interface configured to:
receive control signals intended for the first desynchronized region from the first and second independent desynchronized sub-regions;
pass the control signals intended for the first desynchronized region when in agreement; and
block the control signal intended for the first desynchronized region when not in agreement.

17. The system of claim 16, wherein the delay circuitry of the first and second independent desynchronized sub-regions is different from each other.

18. The system of claim 16, wherein the delay circuitry of the first and second independent desynchronized sub-regions have different physical structure.

19. The system of claim 16, wherein the delay circuitry of the first and second independent desynchronized sub-regions have different controlling algorithms.
